(19) United States
(12) Patent Application Publication
(10) Pub. No.: US 2007/0210246 A1
(43) Pub. Date: Sep. 13, 2007

(54) Stacked image sensor optical module and fabrication method

(75) Inventors: Ronald E. Ellenberger, Phoenix, AZ (US); Shin Sato, Kitakami (JP); Mark Popovich, Chandler, AZ (US)

Correspondence Address: GUNNISON MCKAY & HODGSON, LLP;GARDEN WEST OFFICE PLAZA, SUITE 220, 1900 GARDEN ROAD, MONTEREY, CA, 93940, US

(73) Assignee: Amkor Technology, Inc.

(21) Appl. No.: 11/107,591

(22) Filed: Apr. 14, 2005

(51) Int. Cl. H01L 27/00; H01J 5/02; H01J 40/14

(52) U.S. Cl. 250/239; 250/208.1

(57) ABSTRACT

An optical module includes a substrate, a spacer coupled to the substrate, at least one electronic component, e.g., a passive component, coupled to the substrate, and an image sensor coupled to the spacer. The spacer spaces the image sensor above the at least one electronic component.

### BACKGROUND OF THE INVENTION

1. Field of the Invention

The present invention relates generally to the packaging of electronic components. More particularly, the present invention relates to an optical module and method for fabricating the same.

2. Description of the Related Art

Image sensors are well known to those of skill in the art. An image sensor included an active area, which was responsive to electromagnetic radiation. The image sensor was used to fabricate an optical module, sometimes called a camera module.

The optical module was incorporated into a device such as a digital camera or camera phone. To allow miniaturization of these devices, the optical module should have a minimum size.

### SUMMARY OF THE INVENTION

In accordance with one embodiment, an optical module includes a substrate, a spacer coupled to the substrate, at least one electronic component, e.g., a passive component, coupled to the substrate, and an image sensor coupled to the spacer. The spacer spaces the image sensor above the at least one electronic component.

By stacking the image sensor above the at least one electronic component, use of surface area of the substrate around the image sensor for the at least one electronic component is avoided. More generally, the size of substrate is reduced compared to a substrate of an optical module in which the electronic components are mounted laterally adjacent to the image sensor. Accordingly, the optical module in accordance with this embodiment of the present invention has a small footprint allowing miniaturization of devices such as digital cameras or camera phones using the optical module.

These and other features of the present invention will be more readily apparent from the detailed description set forth below taken in conjunction with the accompanying drawings.

### BRIEF DESCRIPTION OF THE DRAWINGS

FIG. 1 is a top plan view of a portion of an optical module in accordance with one embodiment of the present invention;

FIG. 2 is a cross-sectional view of the optical module taken along the line II-II of FIG. 1;

FIG. 3 is a top plan view of a portion of an optical module in accordance with another embodiment of the present invention;

FIG. 4 is a cross-sectional view of the optical module taken along the line IV-IV of FIG. 3;

FIG. 5 is a top plan view of a portion of an optical module in accordance with another embodiment of the present invention;

FIG. 6 is a cross-sectional view of the optical module taken along the line VI-VI of FIG. 5;

FIGS. 7A, 7B, and 7C are top plan views of a portion of an optical module in accordance with other embodiments of the present invention;

FIG. 8 is a cross-sectional view of the optical module taken along the line VIII-VIII of FIG. 7A; and

FIG. 9 is a stacked image sensor optical module fabrication process in accordance with one embodiment of the present invention.

In the following description, the same or similar elements are labeled with the same or similar reference numbers.

### DETAILED DESCRIPTION

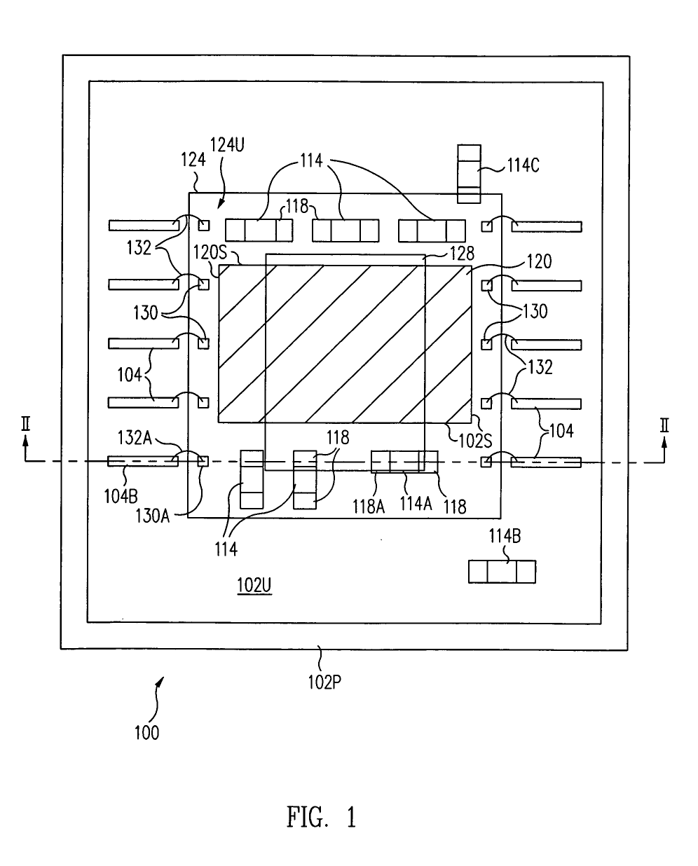

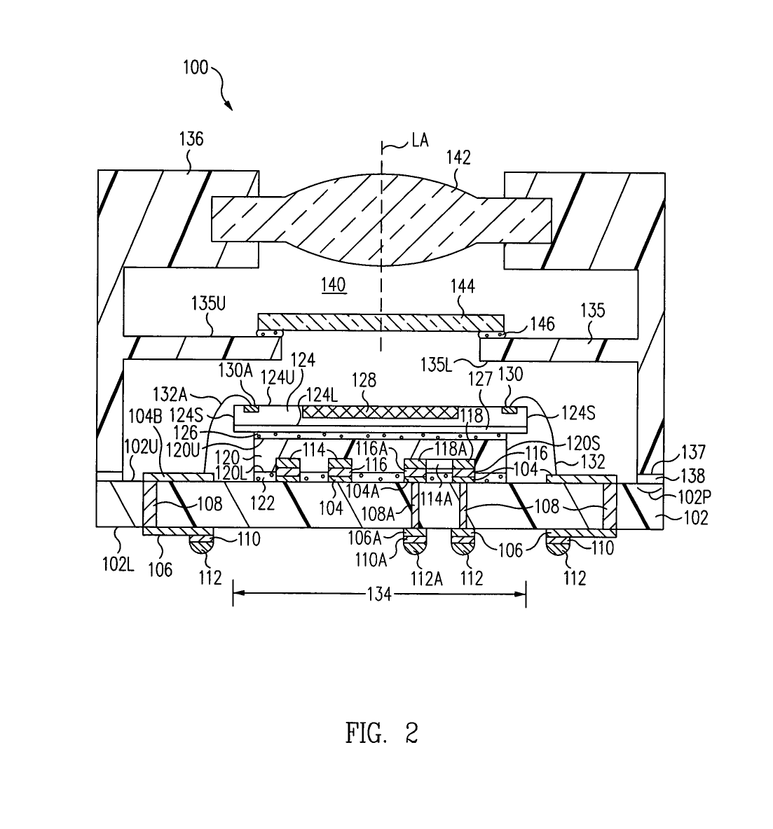

In accordance with one embodiment, referring to FIGS. 1 and 2 together, an optical module 100 includes a substrate 102, a spacer 120 coupled to substrate 102, electronic components 114, e.g., passive components, coupled to substrate 102, and an image sensor 124 coupled to spacer 120. Spacer 120 spaces image sensor 124 above electronic components 114.

By stacking image sensor 124 above electronic components 114, use of surface area of substrate 102 around image sensor 124 for electronic components 114 is avoided. More generally, the size of substrate 102 is reduced compared to a substrate of an optical module in which the electronic components are mounted laterally adjacent to the image sensor. Accordingly, optical module 100 in accordance with this embodiment of the present invention has a small footprint allowing miniaturization of devices such as digital cameras or camera phones using optical module 100.

More particularly, FIG. 1 is a top plan view of a portion of an optical module 100 in accordance with one embodiment of the present invention. FIG. 2 is a cross-sectional view of optical module 100 taken along the line II-II of FIG. 1. Optical module 100 is used in a wide variety of applications, e.g., digital cameras and cellular camera phones.

Optical module 100 includes a substrate 102, e.g., formed of ceramic, pre-molded plastic or laminate, although substrate 102 is formed of other materials in other embodiments. Substrate 102 includes an upper, e.g., first, surface 102U and a lower, e.g., second, surface 102L, opposite upper surface 102U.

Formed on upper surface 102U of substrate 102 are a plurality of electrically conductive upper traces 104, which include first and second upper traces 104A, 104B. Formed on lower surface 102L of substrate 102 are a plurality of electrically conductive lower traces 106, which include a first lower trace 106A. Extending through substrate 102 from lower surface 102L to upper surface 102U are a plurality of electrically conductive vias 108, which include a first via 108A. Lower traces 106 are electrically connected to upper traces 104 by vias 108. To illustrate, lower trace 106A is electrically connected to upper trace 104A by via 108A.

Formed on lower traces 106 are electrically conductive pads 110, which include a first pad 110A. Formed on pads 110 are electrically conductive interconnection balls 112, e.g., solder. To illustrate, pad 110A is formed on lower trace 106A. A first interconnection ball 112A of the plurality of interconnection balls 112 is formed on pad 110A. Interconnection balls 112 are used to connect optical module 100 to a larger substrate such as a printed circuit mother board.

Although a particular electrically conductive pathway between upper traces 104 and interconnection balls 112 is described above, other electrically conductive pathways can be formed. For example, contact metallizations can be formed between the various electrical conductors. Alternatively, pads 110 are not formed and interconnection balls 112 are formed directly on lower traces 106.

Further, instead of straight though vias 108, in one embodiment, substrate 102 is a multi-layer laminate substrate and a plurality of vias and/or internal traces form the electrical interconnection between traces 104 and 106.

In yet another embodiment, interconnection balls 112 are distributed in an array format to form a ball grid array (BGA) type optical module. Alternatively, interconnection balls 112 are not formed, e.g., to form a metal land grid array (LGA) type optical module. In yet another alternative, pads 110/interconnection balls 112 are not formed, e.g., to form a leadless chip carrier (LCC) type optical module. In another embodiment, optical module 100 is inserted into a socket that is pre-mounted on the larger substrate, e.g., on the printed circuit mother board. BGA, LGA and LCC type modules are well known to those of skill in the art.

In another embodiment, a flex connector, sometimes called an edge connector or flex strip, is electrically connected to lower traces 106, e.g., for applications where optical module 100 is remote from the larger substrate. Other electrically conductive pathway modifications will be obvious to those of skill in the art.

One or more electronic components 114 are mounted to upper surface 102U of substrate 102. Electronic components 114 are sometimes referred to as surface mounted components. In one embodiment, electronic components 114 are passive components such as resistors, capacitors, or inductors. In another embodiment, electronic components 114 are active components such as integrated circuit chips. Generally, an active component actively changes an electronic signal whereas a passive component simply has an interaction with an electronic signal. In yet another embodiment, electronic components 114 include both passive components and active components, which are mounted in a flip chip or wirebond configuration.

Although eight electronic components 114 are illustrated in FIGS. 1 and 2, optical module 100 generally includes at least one electronic component 114 and can include more or less than eight electronic components 114.

Electronic components 114 are surface mounted to upper traces 104, for example, with solder 116. More particularly, connector ends 118 of electronic components 114 are mounted to upper traces 104 by solder 116. To illustrate, a first electronic component 114A of the plurality of electronic components 114 includes connector ends 118 including a first connector end 118A. Connector end 118A is mounted to upper trace 104A by solder 116.

Also mounted to upper surface 102U of substrate 102 is a spacer 120, e.g., made of ceramic, silicon, print circuit board material although other materials are used in other embodiments. More particularly, a lower, e.g., first, surface 120L of spacer 120 is mounted to upper surface 102U, for example, with a first adhesive 122, sometimes called a spacer adhesive. Spacer 120 further includes an upper, e.g., second, surface 120U.

Mounted, sometimes called die attached, to upper surface 120U of spacer 120 is an image sensor 124. Image sensor 124 is indicated by the dashed rectangle in FIG. 1 to allow visualization of spacer 120 and electronic components 114, which lie directly below image sensor 124.

More particularly, a lower, e.g., first, surface 124L of image sensor 124 is mounted to upper surface 120U, for example, with a second adhesive 126, sometimes called an image sensor adhesive or die attach adhesive. Although second adhesive 126 is illustrated as covering the entire upper surface 120U of spacer 120 and only partially covering lower surface 124L of image sensor 124, in another embodiment, second adhesive 126 covers the entire lower surface 124L of image sensor 124.

In accordance with one embodiment, an opaque coating 127, sometimes called a light protective coating, is formed on the entire lower surface 124L of image sensor 124. Opaque coating 127, e.g., black epoxy, is opaque to the radiation of interest. Thus, opaque coating 127 prevents radiation from passing through or being reflected by lower surface 124L and the associated interference with the operation of image sensor 124.

In one embodiment, opaque coating 127 is directly attached to second adhesive 126 thus mounting lower surface 124L of image sensor 124 to upper surface 120U of spacer 120. In another embodiment, opaque coating 127 is not formed such that lower surface 124L of image sensor 124 is directly mounted to upper surface 120U of spacer 120 by second adhesive 126. In yet another embodiment, second adhesive 126 is not formed such that lower surface 124L of image sensor 124 is directly mounted to upper surface 120U of spacer 120 by opaque coating 127, e.g., an epoxy.

Image sensor 124 further includes an upper, e.g., second, surface 124U. An active area 128 and bond pads 130 of image sensor 124 are formed on upper surface 124U. In this embodiment, upper surface 102U, lower surface 124L, and upper surface 124U are parallel to one another. Although various structures may be described as being parallel or perpendicular, it is understood that the structures may not be exactly parallel or perpendicular but only substantially parallel or perpendicular to within accepted manufacturing tolerances.

The area, sometimes called the entire area or total area, of upper surface 120U of spacer 120 is less than the area of lower surface 124L of image sensor 124. Accordingly, image sensor 120U extends laterally (sometimes called horizontally) past and overhangs the sides 120S of spacer 120. Generally, sides 120S are perpendicular to and extend between upper surface 120U and lower surface 120L of spacer 120. Although image sensor 124 is illustrated as overhanging all four sides 120S of spacer 120, in other embodiments, image sensor 124 overhangs one, two or three sides 120S of spacer 120.

Electronic components 114 are coupled to upper surface 102U of substrate 102 laterally adjacent spacer 120. Further, electronic components 114 are located directly below image sensor 124, i.e., image sensor 124 overhangs electronic components 124. Stated another way, electronic components are vertically located between upper surface 102U of substrate 102 and lower surface 124L of image sensor 124 such that image sensor 124 is stacked above electronic components 114. Spacer 120 spaces image sensor 124 above electronic components 114.

By stacking image sensor 124 above electronic components 114, use of surface area of upper surface 102U around image sensor 124 for electronic components 114 is avoided. More particularly, instead of allocating additional surface area of upper surface 102U for electronic components 114 beyond that required for image sensor 124 (outward of sides 124S of image sensor 124), electronic components 114 are mounted within an image sensor die attach area 134 of upper surface 102U of substrate 102.

Generally, image sensor die attach area 134 of upper surface 102U of substrate 102 equals the area of lower surface 124L of image sensor 124 projected vertically downwards onto upper surface 102U. Stated another way, if image sensor 124 was directly attached to upper surface 102U of substrate 102 without spacer 120, the area occupied by image sensor 124 on upper surface 102U of substrate 102 is image sensor die attach area 134.

By mounting electronic components 114 within image sensor die attach area 134, the area of upper surface 102U of substrate 102 is minimized. More generally, the size of substrate 102 is reduced compared to a substrate of an optical module in which the electronic components are mounted laterally adjacent to the image sensor. Accordingly, optical module 100 has a small size, sometimes called a small footprint, allowing miniaturization of devices such as digital cameras or camera phones using optical module 100.

However, if desired, one or more of electronic components 114 can be mounted to upper surface 102U of substrate 102 outside of or partially overlapping on image sensor die attach area 134. For example, electronic components 114B, 114C are mounted outside of and partially overlapping on, respectively, image sensor die attach area 134.

Generally, active area 128 of image sensor 124 is responsive to radiation, e.g., electromagnetic radiation, as is well known to those of skill in the art. For example, active area 128 is responsive to infrared radiation, ultraviolet light, and/or visible light. Illustratively, image sensor 124 is a CMOS image sensor device, a charge coupled device (CCD), a pyroelectric ceramic on CMOS device, or an erasable programmable read-only memory device (EPROM) although other image sensors are used in other embodiments.

A set of upper traces 104 are electrically connected to bond pads 130 by bond wires 132. To illustrate, a first bond pad 130A of the plurality of bond pads 130 is electrically connected to upper trace 104B by a first bond wire 132A of the plurality of bond wires 132.

A lens holder 136 is mounted to substrate 102, e.g., by a third adhesive 138, sometimes called a lens holder adhesive. Lens holder 136 and third adhesive 138 are not illustrated in FIG. 1.

In one embodiment, lens holder 136 includes an annular rectangular mounting surface 137, which is coupled to a periphery 102P of upper surface 102U of substrate 102. Periphery 102P is an annular rectangular mounting surface corresponding to annular rectangular mounting surface 137 of lens holder 136.

Lens holder 136 includes a central aperture 140 having a longitudinal axis LA perpendicular to upper surface 124U of image sensor 124. Central aperture 140 extends upwards and is aligned above active area 128.

Lens holder 136 supports an optical element 142 such as a single lens or multiple lenses, e.g., one, two, three, four or more lenses made of plastic or glass, stacked together to form a lens system. In one embodiment, optical element 142 is threadedly attached to lens holder 136 such that rotation of optical element 142 moves optical element 142 relative to lens holder 136.

In another embodiment, optical element 142 is fixedly attached to lens holder 136, e.g., with adhesive. In accordance with this embodiment, optical element 142 is sometimes called a fixed focus lens.

A window 144 is mounted to lens holder 136 downwards and below optical element 142. Illustratively, window 144 is mounted to an upper, e.g., first, surface 135U of a window support 135 of lens holder 136 with a fourth adhesive 146, sometimes called a window adhesive. However, in another embodiment, window 144 is mounted to a lower, e.g., second, surface 135L of window support 135 of lens holder 136 with adhesive 146.

In one embodiment, window 144 includes a filter, e.g., an infrared filter. Accordingly, window 144 is sometimes called an IR glass.

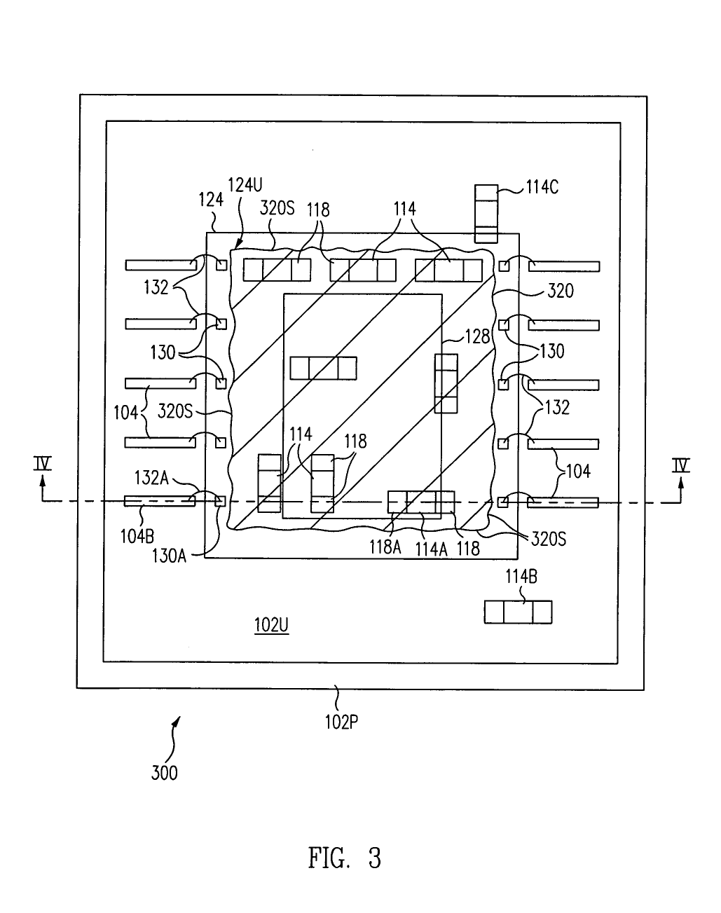

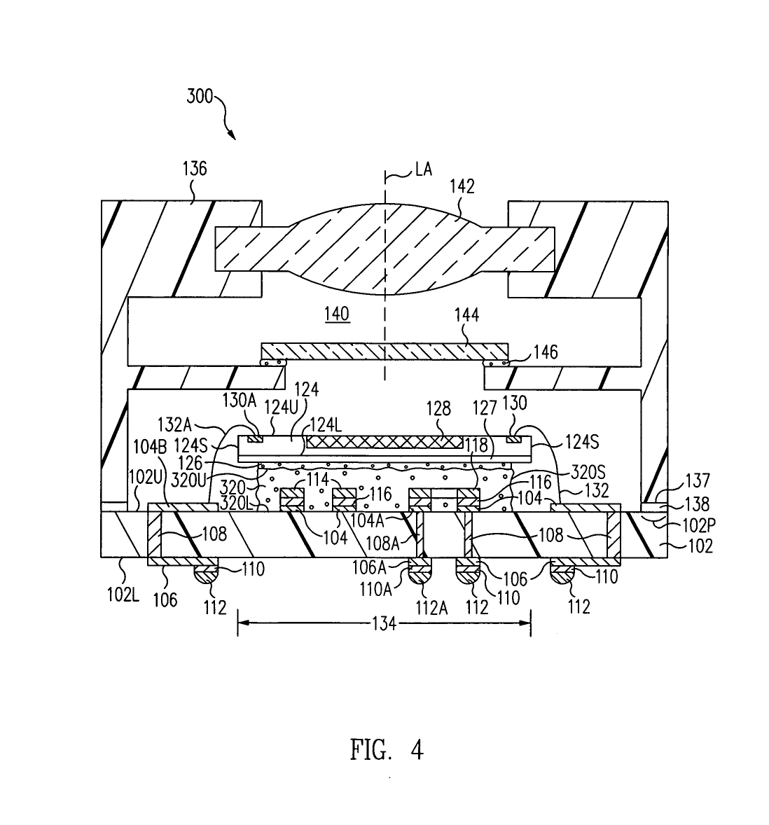

FIG. 3 is a top plan view of a portion of an optical module 300 in accordance with one embodiment of the present invention. FIG. 4 is a cross-sectional view of optical module 300 taken along the line IV-IV of FIG. 3. Optical module 300 of FIGS. 3 and 4 is similar to optical module 100 of FIGS. 1 and 2 and only the significant differences between optical module 100 and optical module 300 are discussed below.

Referring now to FIGS. 3 and 4 together, optical module 300 includes a spacer 320 mounted to upper surface 102U of substrate 102. In one embodiment, spacer 320 is an epoxy, e.g., either a liquid epoxy or a film type epoxy, that has been cured. As discussed further below, electronic components 114 are covered by and enclosed within, sometimes called encapsulated or embedded, within spacer 320.

More particularly, a lower, e.g., first, surface 320L of spacer 320 is mounted to upper surface 102U. Illustratively, spacer 320 itself, e.g., an epoxy, is directly attached to upper surface 102U. Spacer 320 further includes an upper, e.g., second, surface 320U.

Mounted to upper surface 320U of spacer 320 is image sensor 124. Image sensor 124 is indicated by the dashed rectangle in FIG. 3 to allow visualization of spacer 320 and electronic components 114, which lie directly below image sensor 124.

More particularly, lower surface 124L of image sensor 124 is mounted to upper surface 320U, for example, with second adhesive 126. In accordance with one embodiment, opaque coating 127 is formed on the entire lower surface 124L of image sensor 124.

In one embodiment, opaque coating 127 is directly attached to second adhesive 126 thus mounting lower surface 124L of image sensor 124 to upper surface 320U of spacer 320. In another embodiment, opaque coating 127 is not formed such that lower surface 124L of image sensor 124 is directly mounted to upper surface 320U of spacer 320 by second adhesive 126. In yet another embodiment, second adhesive 126 is not formed such that lower surface 124L of image sensor 124 is directly mounted to upper surface 320U of spacer 320 by opaque coating 127, e.g., an epoxy.

In yet another embodiment, lower surface 124L of image sensor 124 is directly mounted to upper surface 320U of spacer 320. In accordance with this embodiment, spacer 320 acts as the adhesive, e.g., is an epoxy, which bonds directly to lower surface 124L of image sensor 124.

Electronic components 114 are coupled to upper surface 102U of substrate 102 within spacer 320. Illustratively, a liquid epoxy or a film type epoxy is applied on to and over electronic components 114 and cured to form spacer 320. This allows electronic components 114 to be located directly below image sensor 124, i.e., image sensor 124 is spaced above electronic components 124 by spacer 320.

By stacking image sensor 124 above electronic components 114, use of surface area of upper surface 102U around image sensor 124 for electronic components 114 is avoided. More particularly, instead of allocating additional surface area of upper surface 102U for electronic components 114 beyond that required for image sensor 124 (outward of sides 124S of image sensor 124), electronic components 114 are mounted within image sensor die attach area 134 of upper surface 102U of substrate 102.

By mounting electronic components 114 within image sensor die attach area 134, the area of upper surface 102U of substrate 102 is minimized. More generally, the size of substrate 102 is reduced compared to a substrate of an optical module in which the electronic components are mounted laterally adjacent to the image sensor. Accordingly, optical module 300 has a small size, sometimes called a small footprint, allowing miniaturization of devices such as digital cameras or camera phones using optical module 300.

As illustrated, the area of upper surface 320U of spacer 320 is less than the area of lower surface 124L of image sensor 124. Accordingly, image sensor 124 extends laterally (sometimes called horizontally) past and overhangs the sides 320S of spacer 320. Generally, sides 320S are perpendicular to and extend between upper surface 320U and lower surface 320L of spacer 320. Although image sensor 124 is illustrated as overhanging all four sides 120S of spacer 320, in other embodiments, image sensor 124 overhangs one, two or three sides 320S of spacer 320S.

However, in other embodiments, the area of upper surface 320U of spacer 320 is equal to or greater than the area of lower surface 124L of image sensor 124.

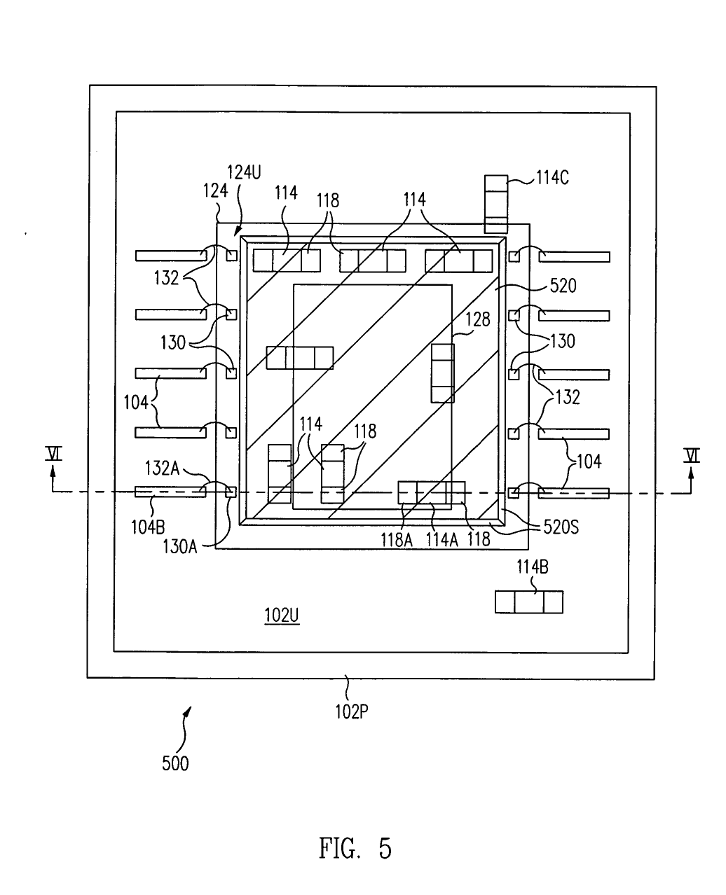

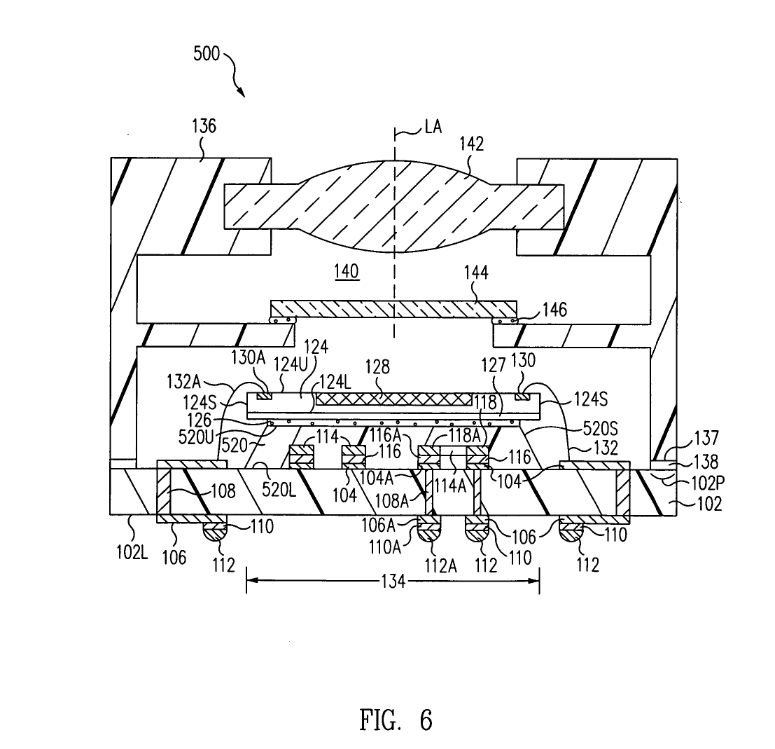

FIG. 5 is a top plan view of a portion of an optical module 500 in accordance with one embodiment of the present invention. FIG. 6 is a cross-sectional view of optical module 500 taken along the line VI-VI of FIG. 5. Optical module 500 of FIGS. 5 and 6 is similar to optical module 100 of FIGS. 1 and 2 and only the significant differences between optical module 100 and optical module 500 are discussed below.

Referring now to FIGS. 5 and 6 together, optical module 500 includes a spacer 520 mounted to upper surface 102U of substrate 102. In one embodiment, spacer 520 is molding compound that has been injected into a mold such as a pin gate mold and cured. Accordingly, spacer 520 is sometimes called a mold cap. As discussed further below, electronic components 114 are covered by and enclosed within, sometimes called encapsulated or embedded, within spacer 520.

More particularly, a lower, e.g., first, surface 520L of spacer 520 is mounted to upper surface 102U. Illustratively, spacer 520 is molded directly onto upper surface 102U such that spacer 520 directly adheres to upper surface 102U. Spacer 520 further includes an upper, e.g., second, surface 520U.

Mounted to upper surface 520U of spacer 520 is image sensor 124. Image sensor 124 is indicated by the dashed rectangle in FIG. 5 to allow visualization of spacer 520 and electronic components 114, which lie directly below image sensor 124.

More particularly, lower surface 124L of image sensor 124 is mounted to upper surface 520U, for example, with second adhesive 126, e.g., a paste or film die attach adhesive. In accordance with one embodiment, opaque coating 127 is formed on the entire lower surface 124L of image sensor 124.

In one embodiment, opaque coating 127 is directly attached to second adhesive 126 thus mounting lower surface 124L of image sensor 124 to upper surface 520U of spacer 520. In another embodiment, opaque coating 127 is not formed such that lower surface 124L of image sensor 124 is directly mounted to upper surface 520U of spacer 520 by second adhesive 126. In yet another embodiment, second adhesive 126 is not formed such that lower surface 124L of image sensor 124 is directly mounted to upper surface 520U of spacer 520 by opaque coating 127, e.g., an epoxy.

Electronic components 114 are coupled to upper surface 102U of substrate 102 within spacer 520. Illustratively, substrate 102 including electronic components 114 are placed into a mold such as a pin gate mold. Molding compound is injected into the mold and around electronic components 114. The molding compound is cured to form spacer 520, and substrate 102 is removed from the mold. This allows electronic components 114 to be located directly below image sensor 124, i.e., image sensor 124 is spaced above electronic components 124 by spacer 520.

By stacking image sensor 124 above electronic components 114, use of surface area of upper surface 102U around image sensor 124 for electronic components 114 is avoided. More particularly, instead of allocating additional surface area of upper surface 102U for electronic components 114 beyond that required for image sensor 124 (outward of sides 124S of image sensor 124), electronic components 114 are mounted within image sensor die attach area 134 of upper surface 102U of substrate 102.

By mounting electronic components 114 within image sensor die attach area 134, the area of upper surface 102U of substrate 102 is minimized. More generally, the size of substrate 102 is reduced compared to a substrate of an optical module in which the electronic components are mounted laterally adjacent to the image sensor. Accordingly, optical module 500 has a small size, sometimes called a small footprint, allowing miniaturization of devices such as digital cameras or camera phones using optical module 500.

As illustrated, the area of upper surface 520U of spacer 520 is less than the area of lower surface 124L of image sensor 124. Accordingly, image sensor 124 extends laterally (sometimes called horizontally) past and overhangs the sides 520S of spacer 520. Although image sensor 124 is illustrated as overhanging all four sides 520S of spacer 520, in other embodiments, image sensor 124 overhangs one, two or three sides 520S of spacer 520S.

However, in other embodiments, the area of upper surface 520U of spacer 520 is equal to or greater than the area of lower surface 124L of image sensor 124.

As shown in FIG. 6, sides 520S of spacer 520 are slanted. More particularly, the area of lower surface 520L of spacer 520 is greater than the area of upper surface 520U of spacer 520 and sides 520S slant inwards from lower surface 520L to upper surface 520U. However, in another embodiment, sides 520S extend between and are perpendicular to lower surface 520L and upper surface 520U.

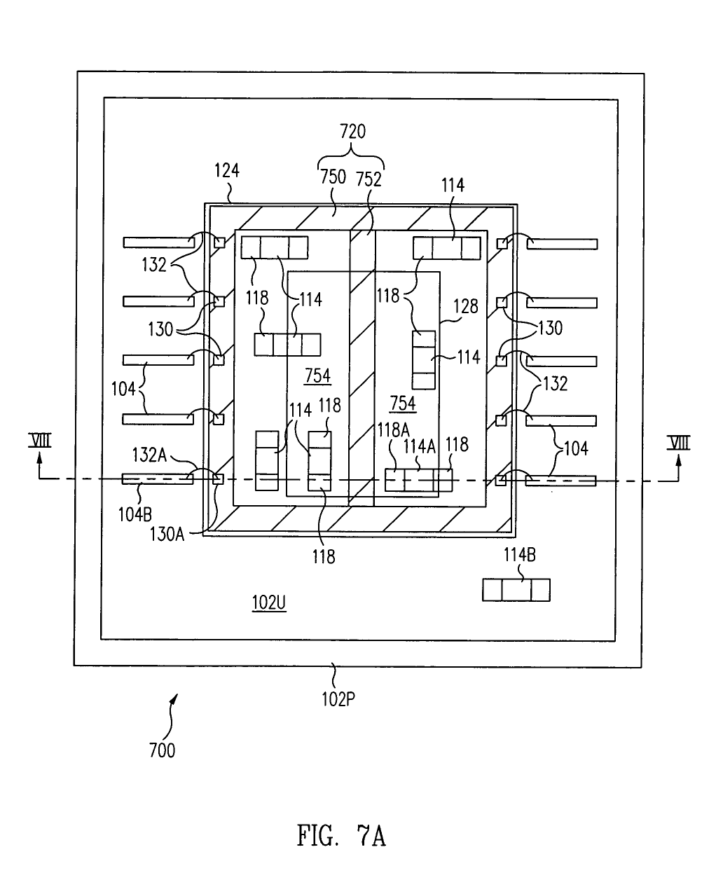

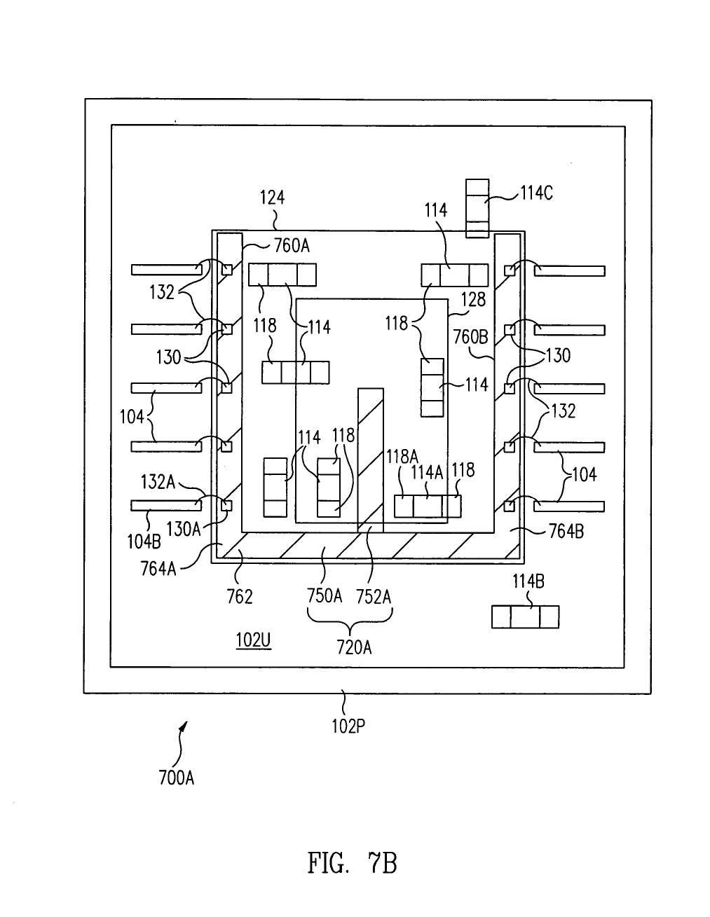

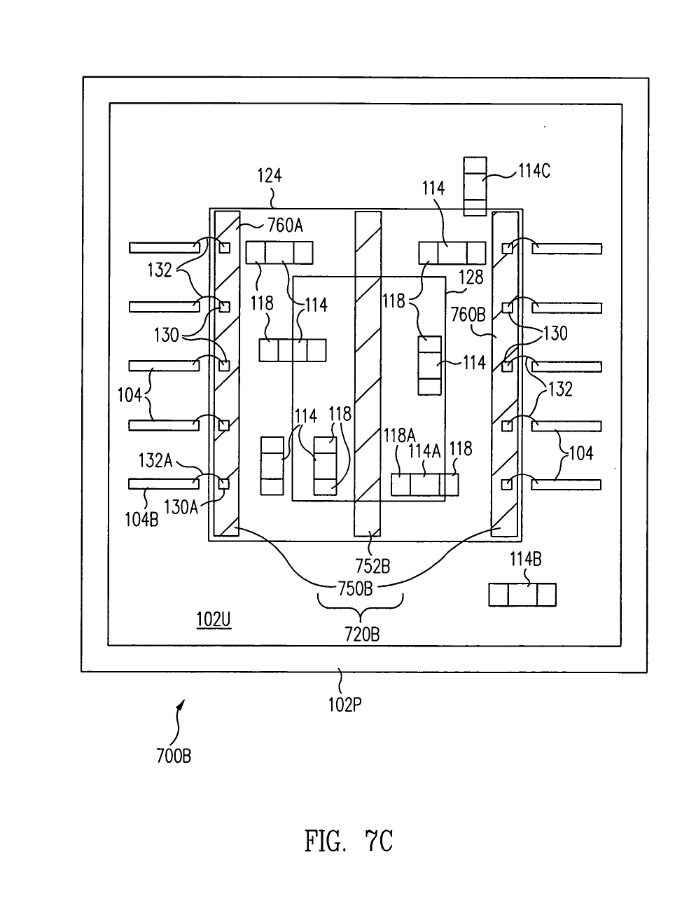

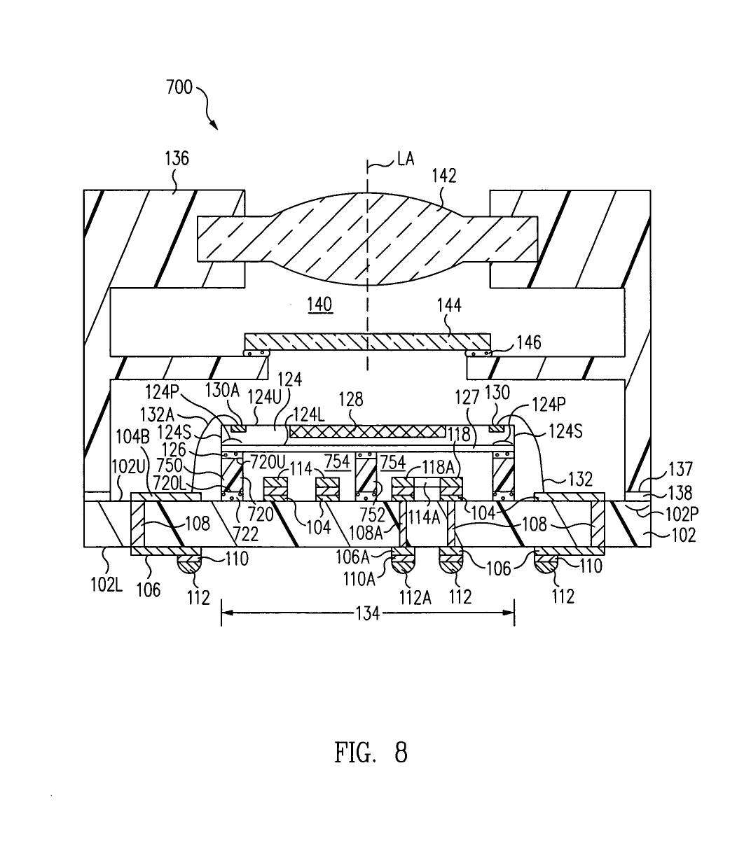

FIG. 7A is a top plan view of a portion of an optical module 700 in accordance with one embodiment of the present invention. FIG. 8 is a cross-sectional view of optical module 700 taken along the line VIII-VIII of FIG. 7A. Optical module 700 of FIGS. 7A and 8 is similar to optical module 100 of FIGS. 1 and 2 and only the significant differences between optical module 100 and optical module 700 are discussed below.

Referring now to FIGS. 7A and 8 together, optical module 700 includes a spacer 720 mounted to upper surface 102U of substrate 102. In one embodiment, spacer 720 is made of ceramic, silicon, print circuit board material although other materials are used in other embodiments. As discussed further below, electronic components 114 are surrounded by spacer 720, which forms a platform to support image sensor 124 above electronic components 114. Although spacer 720 is illustrated as completely surrounding electronic components 114, in other embodiments, an optical module is formed with a spacer that does not completely surround the electronic components 114. Illustratively, some of electronic components 114 are mounted outside of the area of the spacer and/or outside of image sensor die attach area 134.

More particularly, a lower, e.g., first, surface 720L of spacer 720 is mounted to upper surface 102U, e.g., with a first adhesive 722, sometimes called a spacer adhesive. Illustratively, first adhesive 722 is solder or epoxy. Spacer 720 further includes an upper, e.g., second, surface 720U.

Mounted to upper surface 720U of spacer 720 is image sensor 124. Image sensor 124 is indicated by the dashed rectangle in FIG. 7A to allow visualization of spacer 720 and electronic components 114, which lie directly below image sensor 124.

More particularly, lower surface 124L of image sensor 124 is mounted to upper surface 720U, for example, with second adhesive 126, e.g., a paste or film die attach adhesive. In accordance with one embodiment, opaque coating 127 is formed on the entire lower surface 124L of image sensor 124.

In one embodiment, opaque coating 127 is directly attached to second adhesive 126 thus mounting lower surface 124L of image sensor 124 to upper surface 720U of spacer 720. In another embodiment, opaque coating 127 is not formed such that lower surface 124L of image sensor 124 is directly mounted to upper surface 720U of spacer 720 by second adhesive 126. In yet another embodiment, second adhesive 126 is not formed such that lower surface 124L of image sensor 124 is directly mounted to upper surface 720U of spacer 720 by opaque coating 127, e.g., an epoxy.

Electronic components 114 are coupled to upper surface 102U of substrate 102 and surrounded by spacer 720. Spacer 720 is coupled to and supports the periphery 124P of lower surface 124L of image sensor 124. More particularly, spacer 720 includes a rectangular annular foundation 750, sometimes called a rectangular ring or square ring, and a center support wall 752 extending between opposite sides of rectangular annular foundation 750. In one embodiment, spacer 720 is formed without center support wall 752.

Illustratively, spacer 720 is integral, i.e., is a single piece and not a plurality of separate pieces connected together. In another embodiment, spacer 720 is formed from a plurality of separate pieces coupled together or individually mounted to upper surface 102U of substrate 102.

Spacer 720 defines at least one, e.g., two, electronic component cavities 754 therein. Electronic component cavities 754 are directly below image sensor 124. Electronic components 114 are located within electronic component cavities 754 directly below image sensor 124.

This allows electronic components 114 to be located directly below image sensor 124, i.e., image sensor 124 is spaced above electronic components 124 by spacer 720.

By stacking image sensor 124 above electronic components 114, use of surface area of upper surface 102U around image sensor 124 for electronic components 114 is avoided. More particularly, instead of allocating additional surface area of upper surface 102U for electronic components 114 beyond that required for image sensor 124 (outward of sides 124S of image sensor 124), electronic components 114 are mounted within image sensor die attach area 134 of upper surface 102U of substrate 102.

By mounting electronic components 114 within image sensor die attach area 134, the area of upper surface 102U of substrate 102 is minimized. More generally, the size of substrate 102 is reduced compared to a substrate of an optical module in which the electronic components are mounted laterally adjacent to the image sensor. Accordingly, optical module 700 has a small size, sometimes called a small footprint, allowing miniaturization of devices such as digital cameras or camera phones using optical module 700.

FIG. 7B is a top plan view of a portion of an optical module 700A in accordance with one embodiment of the present invention. Optical module 700A of FIG. 7B is similar to optical module 700 of FIG. 7A except that only a portion of spacer 720 of FIG. 7A is used to form a spacer 720A of optical module 700A of FIG. 7B.

In accordance with this embodiment, spacer 720A includes a U-shaped foundation 750A and a center support wall 752A. U-shaped foundation includes two parallel sidewalls 760A, 760B and a perpendicular base 762 extending between ends 764A, 764B of sidewalls 760A, 760B, respectively. Center support wall 752 is perpendicular to base 762 and parallel to sidewalls 760A, 760B. Center support wall 752 extends from base 762 about half the length of sidewalls 760A, 760B.

FIG. 7C is a top plan view of a portion of an optical module 700B in accordance with one embodiment of the present invention. Optical module 700B of FIG. 7C is similar to optical module 700 of FIG. 7A except that only a portion of spacer 720 of FIG. 7A is used to form a spacer 720B of optical module 700B of FIG. 7C.

In accordance with this embodiment, spacer 720B includes a foundation 750B and a center support wall 752B. Foundation 750B includes two parallel sidewalls 760A, 760B. Center support wall 752B is parallel to and between sidewalls 760A, 760B. Further, center support wall 752B is equal in length to sidewalls 760A, 760B.

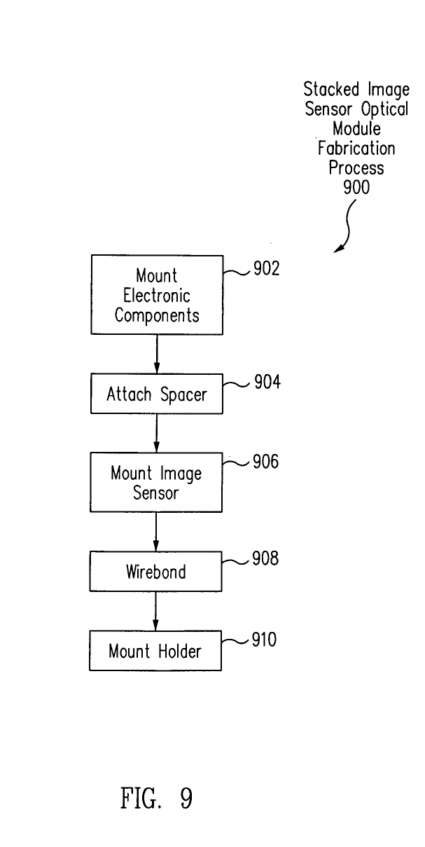

FIG. 9 is a stacked image sensor optical module fabrication process 900 in accordance with one embodiment of the present invention. Referring now to FIGS. 1 and 9 together, in a mount electronic components operation 902, electronic components 114 are mounted within image sensor die attach area 134 of upper surface 102U of substrate 102. Illustratively, electronic components 114 are mounted using a surface mount technique, e.g., by applying solder paste and reflowing the solder paste to form solder 116 between connector ends 118 and a set of upper traces 104.

In an attach spacer operation 904, spacer 120 is mounted to upper surface 102U, e.g., using first adhesive 122. Illustratively, first adhesive 122 is applied between spacer and upper surface 102U and cured.

Referring to FIGS. 3 and 9, in one embodiment, a liquid epoxy or a film type epoxy is applied on to and over electronic components 114 and upper surface 102U and cured to form spacer 320 in attach spacer operation 904.

In another embodiment, referring to FIGS. 5 and 9, in attach spacer operation 904, substrate 102 including electronic components 114 are placed into a mold such as a pin gate mold. Molding compound is injected into the mold and around electronic components 114. The molding compound is cured to form spacer 520, and substrate 102 is removed from the mold.

In yet another embodiment, referring to FIGS. 7 and 9, in attach spacer operation 904, lower surface 720L of spacer 720 is mounted to upper surface 102U with first adhesive 722. Illustratively, spacer 720 is mounted to substrate 102 by applying solder paste between lower surface 720L and upper surface 102U, and reflowing the solder paste. In another embodiment, spacer 720 is mounted to substrate 102 by applying epoxy between lower surface 720L and upper surface 102U, and curing the epoxy to form adhesive 722.

Referring again to FIG. 9, in a mount image sensor operation 906, image sensor 124 is mounted to spacer 120, 320, 520, 720, 720A, 720B of FIGS. 1, 3, 5, 7A, 7B, 7C, respectively, as discussed above.

In a wirebond operation 908, bond wires 132, e.g., gold bond wires, are formed between bond pads 130 of image sensor 124 and a set of upper traces 104.

In a mount holder operation 910, lens holder 136 is mounted to substrate 102 as discussed above.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

1. An optical module comprising:
a substrate;
a spacer directly adhered to the substrate;
at least one electronic component coupled to the substrate, the at least one electronic component being encapsulated in the spacer; and
an image sensor coupled to the spacer, the spacer spacing the image sensor above the at least one electronic component.

2. The optical module of claim 1 wherein the at least one electronic component is located directly below the image sensor.

3. The optical module of claim 1 wherein the at least one electronic component is coupled to a first surface of the substrate, the at least one electronic component being vertically located between the first surface of the substrate and a first surface of the image sensor.

4. The optical module of claim 1 wherein the image sensor is stacked above the at least one electronic component.

5. The optical module of claim 1 wherein the at least one electronic component is mounted within an image sensor die attach area of a first surface of the substrate.

6. The optical module of claim 1 further comprising an opaque coating on a first surface of the image semsor.

7. The optical module of claim 6 wherein the image sensor comprises a second surface comprising:
an active area responsive to electromagnetic radiation; and
bond pads.

8. The optical module of claim 7 further comprising bond wires electrically coupling the bond pads to traces on a first surface of the substrate.

9. The optical module of claim 1 further comprising:
a lens holder coupled to the substrate;
a optical element coupled to the lens holder; and
a window coupled to the lens holder.

10. The optical module of claim 1 wherein the at least one electronic component comprises a passive component.

11. The optical module of claim 1 further comprising solder mounting the at least one electronic component to the substrate.

12. The optical module of claim 11 wherein terminals of the at least one electronic component are coupled to the substrate by the solder.

13. The optical module of claim 1 further comprising:
an adhesive coupling a first surface of the image sensor to a surface of the spacer.

14. The optical module of claim 13 wherein the area of the surface of the spacer is less than the area of the first surface of the image sensor.

15-18. (canceled)

19. An optical module comprising:
a substrate;
at least one electronic component coupled to the substrate;
a spacer directly adhered to the substrate, the at least one electronic component being encapsulated within the spacer; and
an image sensor coupled to the spacer, the spacer spacing the image sensor above the at least one electronic component.

20. The optical module of claim 19 wherein the spacer comprises molding compound.

21. The optical module of claim 19 wherein the spacer comprises an epoxy.

22. A method comprising:
mounting at least one electronic component to a substrate;
attaching a spacer to the substrate comprising encapsulating the at least one electronic component within the spacer, the spacer being directly adhered to the substrate; and
spacing an image sensor above the at least one electronic component with the spacer.

23. The method of claim 22 wherein the mounting at least one electronic component to a substrate comprises surface mounting the at least one electronic component to an image sensor die attach area of the substrate.
